(19) United States
(12) Patent Application Publication
(10) Pub. No.: US 2015/0108484 A1
(43) Pub. Date: Apr. 23, 2015

(54) FLEXIBLE DISPLAY DEVICE AND METHOD OF MANUFACTURING THE FLEXIBLE DISPLAY DEVICE

(71) Applicant: SAMSUNG DISPLAY CO., LTD., Yongin-City (KR)

(72) Inventors: Gyung-Soon Park, Seoul (KR); Dong-Woo Kim, Seongnam-si (KR)

(21) Appl. No.: 14/506,594

(22) Filed: Oct. 3, 2014

(30) Foreign Application Priority Data
Oct. 23, 2013 (KR) 10-2013-0126611

(51) Int. Cl. H01L 27/12; H01L 51/00; H01L 51/56; H01L 27/32

(52) U.S. Cl. CPC H01L 27/1255; H01L 27/3248; H01L 51/0097; H01L 51/56; H01L 27/1259; H01L 2227/323
USPC 257/71; 438/23

(57) ABSTRACT

A flexible display device includes a flexible base substrate, a semiconductor pattern, a gate insulation layer, and a gate electrode on the base substrate, the gate insulation layer between the semiconductor pattern and the gate electrode, a conductive pattern including a source electrode and a drain electrode, the source and drain electrodes overlapping respective sides of the semiconductor pattern, an insulation interlayer on the gate insulation layer, between the gate electrode and the conductive pattern, and having at least one stress relief opening at a region exposed by the conductive pattern, and a protection layer on the insulation interlayer and filling the stress relief opening.

### CROSS-REFERENCE TO RELATED APPLICATION

This application claims priority to and the benefit of Korean Patent Application No. 2013-0126611, filed on Oct. 23, 2013 in the Korean Intellectual Property Office (KIPO), the entire content of which is herein incorporated by reference.

### BACKGROUND

1. Field

Aspects of example embodiments are directed toward a flexible display device and a method of manufacturing the flexible display device.

2. Description of the Related Art

An organic light emitting display (“OLED”) element may include a layer of organic materials between two electrodes, that is, an anode and a cathode. Positive holes from the anode may be coupled with electrons from the cathode in the organic layer between the anode and the cathode to emit light. The OLED element may have a variety of features, such as a wide viewing angle, a rapid response rate, relatively thin thickness, and low power consumption.

Recently, the OLED element has been used to manufacture a flexible display device. The flexible display device may include a first conductive pattern including a gate line, a second conductive pattern including a data line and a driving voltage line, and an insulation interlayer including inorganic layers between the first and second conductive patterns.

However, the insulation interlayer may be torn or cracked due to a stress generated when the flexible display device is bent. Thus, electrical properties of a transistor or a capacitor included in the flexible display device may be changed or may vary according to bending of the flexible display device.

### SUMMARY

Aspects of example embodiments are directed toward flexible display devices having a structure capable of relieving a stress generated when the flexible display device is bent.

Aspects of example embodiments are also directed toward methods of manufacturing the flexible display device.

According to example embodiments, a flexible display device includes a flexible base substrate, a semiconductor pattern, a gate insulation layer, and a gate electrode on the base substrate, the gate insulation layer being between the semiconductor pattern and the gate electrode, a conductive pattern including a source electrode and a drain electrode, the source and drain electrodes overlapping respective sides of the semiconductor pattern, an insulation interlayer on the gate insulation layer, between the gate electrode and the conductive pattern, and having at least one stress relief opening at a region exposed by the conductive pattern, and a protection layer on the insulation interlayer and filling the at least one stress relief opening.

In example embodiments, the insulation interlayer may include a first insulation interlayer and a second insulation interlayer, the first insulation layer and the second insulation layer may be stacked (e.g., sequentially stacked) on the gate insulation layer, and the first and second insulation layers may include inorganic materials different from each other.

In example embodiments, the at least one stress relief opening may penetrate the second insulation interlayer.

In example embodiments, the at least one stress relief opening may penetrate the second and first insulation interlayers.

In example embodiments, a plurality of insulation interlayer patterns may be in the at least one stress relief opening.

In example embodiments, each of the plurality of the insulation interlayer patterns may extend in a same direction.

In example embodiments, the flexible display device may further include a capacitor on the base substrate and including a first capacitor electrode and a second capacitor electrode.

In example embodiments, the conductive pattern may further include a data line and a driving voltage line.

In example embodiments, the at least one stress relief opening may be between the data line and the driving voltage line.

In example embodiments, the flexible display device may further include a first electrode on the protection layer and coupled to (e.g., connected to) the drain electrode, a light emitting structure on the first electrode, and a second electrode on the light emitting structure.

According to example embodiments, a method of manufacturing a flexible display device includes forming a semiconductor pattern, a gate electrode, and a gate insulation layer on a base substrate, the gate insulation layer being between the semiconductor pattern and the gate electrode; forming an insulation interlayer on the gate insulation layer and covering the gate electrode and the semiconductor pattern; forming a conductive pattern on the insulation interlayer, the conductive pattern including a source electrode and a drain electrode; forming at least one stress relief opening at a region of the insulation interlayer exposed by the conductive pattern; forming a protection layer on the insulation interlayer and filling the at least one stress relief opening.

In example embodiments, the forming of the insulation interlayer may include forming a first insulation interlayer on the gate insulation layer, and forming a second insulation interlayer on the first insulation interlayer, the second insulation interlayer may include an inorganic material different than that of the first insulation interlayer.

In example embodiments, the forming of the at least one stress relief opening may include etching the second insulation interlayer utilizing the conductive pattern as an etching mask.

In example embodiments, the forming of the at least one stress relief opening may include etching the second and first insulation interlayers utilizing the conductive pattern as an etching mask.

In example embodiments, the forming of the at least one stress relief opening may include forming a photoresist pattern on the insulation interlayer, the photoresist pattern may have a plurality of slits, and patterning the insulation interlayer utilizing the photoresist pattern as an etching mask.

In example embodiments, the method of manufacturing the flexible display device may further include forming a first capacitor electrode on the base substrate, and forming a second capacitor electrode overlapping the first capacitor electrode.

In example embodiments, the conductive pattern may further include a data line and a driving voltage line.

In example embodiments, the at least one stress relief opening may be between the data line and the driving voltage line.

In example embodiments, the forming of the conductive pattern on the insulation interlayer may include forming contact openings penetrating the insulation interlayer to partially expose respective sides of the semiconductor pattern, and electrically coupling the source electrode and the drain electrode to the respective sides of the semiconductor pattern through the contact openings.

In example embodiments, the method of manufacturing the flexible display device may further include forming a first electrode on the protection layer, the first electrode being coupled to the drain electrode, forming a light emitting structure on the first electrode, and forming a second electrode on the light emitting structure

According to example embodiments, a flexible display device may include a first conductive pattern including a gate line, a second conductive pattern including a data line and a voltage driving line, and an insulation interlayer between the first and second conductive lines and including inorganic layers. Stress relief openings may be in portions of the insulation interlayer exposed by the second conductive pattern.

The stress relief openings may relieve a stress generated when the flexible display panel is bent. Thus, cracking or tearing may be prevented from occurring in the insulation interlayer due to the generated stress, and mechanical and electrical properties of the flexible display panel may be improved.

### BRIEF DESCRIPTION OF THE DRAWINGS

Example embodiments will be more clearly understood from the following detailed description taken in conjunction with the accompanying drawings. FIGS. 1 to 24 represent non-limiting, example embodiments as described herein.

FIG. 1 is a plan view illustrating a flexible display device in accordance with example embodiments.

FIG. 2 is a cross-sectional view illustrating the flexible display device shown in FIG. 1.

FIGS. 3 to 11 are cross-sectional views illustrating a method of manufacturing a flexible display device in accordance with example embodiments.

FIG. 12 is a cross-sectional view illustrating a flexible display device in accordance with example embodiments.

FIGS. 13 to 21 are cross-sectional views illustrating a method of manufacturing a flexible display device in accordance with example embodiments.

FIG. 22 is a plan view illustrating the second conductive pattern shown in FIG. 20.

FIG. 23 is a cross-sectional view taken along the line I-I′ in FIG. 22.

FIG. 24 is a cross-sectional view illustrating a stress relief opening in accordance with another example embodiment.

### DETAILED DESCRIPTION

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete and will fully convey the scope of example embodiments to those skilled in the art. In the drawings, the sizes and relative sizes of layers and regions may be exaggerated for clarity.

It will be understood that when an element or layer is referred to as being “on,” “connected to”, or “coupled to” another element or layer, it can be directly on, connected, or coupled to the other element or layer, or one or more intervening elements or layers may also be present. When an element is referred to as being “directly on,” “directly connected to”, or “directly coupled to” another element or layer, there are no intervening elements or layers present. Like numerals refer to like elements throughout. As used herein, the term “and/or” includes any and all combinations of one or more of the associated listed items. Further, the use of “may” when describing embodiments of the present invention relates to “one or more embodiments of the present invention”.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein interpreted accordingly.

The terminology used herein is for the purpose of describing particular example embodiments only and is not intended to be limiting of example embodiments. As used herein, the singular forms “a,” “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

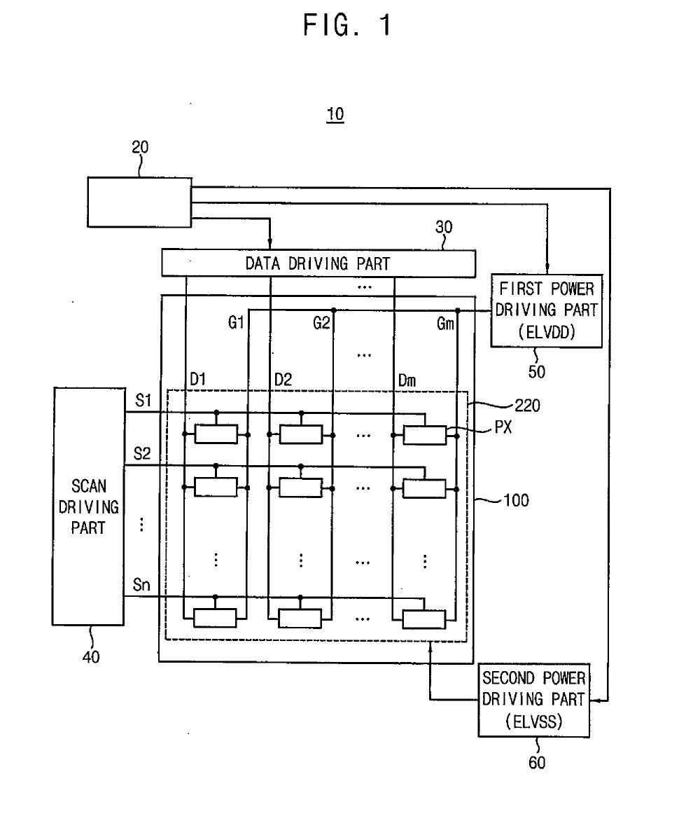

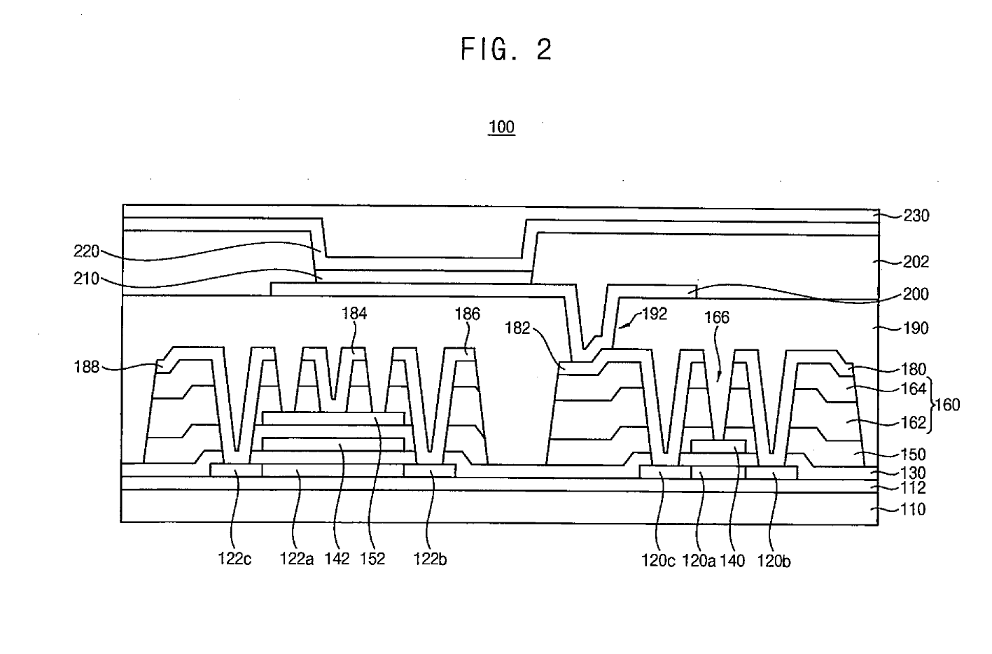

FIG. 1 is a plan view illustrating a flexible display device in accordance with example embodiments. FIG. 2 is a cross-sectional view illustrating the flexible display device shown in FIG. 1.

Referring to FIGS. 1 and 2, a flexible display device 10 may include a flexible display panel 100, a data driving part 30, a scan driving part 40, a first power driving part 50, a second power driving part 60, and a timing controlling part 20.

The flexible display panel 100 may include a plurality of pixels PX, a plurality of gate lines S1, S2, . . . Sn, a plurality of data lines D1, D2, . . . Dm, and a plurality of driving voltage lines G1, G2, . . . Gm.

Each of the pixels PX displays an image based on a scan signal, a data signal, a first driving voltage, and a second driving voltage through (e.g., transmitted through) the gate lines S1, S2, . . . Sn, the data lines D1, D2, . . . Dm, the driving voltage lines G1, G2, . . . Gm, and a second electrode 220. In this embodiment, each of the pixels PX may include an organic light emitting display element. Alternatively, each of the pixels PX may include various display elements such as a liquid crystal element, an electrophoretic element, a plasma display element, etc.

The data driving part 30 may apply (e.g., may transmit) the data signal to the data lines D1, D2, . . . Dm based on a data control signal from the timing controlling part 20.

The first power driving part 50 may apply (e.g., may transmit) the first driving voltage from the timing controlling part 20 to the driving voltage lines G1, G2, . . . Gm. The second power driving part 60 may apply (e.g., may transmit) the second driving voltage from the timing controlling part 20 to the second electrode 220. When each of the pixels PX includes a voltage driving element, the first and second power driving parts 50 and 60 may be omitted. Examples of the voltage driving elements may include a liquid crystal element, an electrophoretic element, etc.

The scan driving part 40 may apply (e.g., may transmit) the scan signal to the gate lines S1, S2, . . . Sm based on a gate control signal from the timing controlling part 20.

The timing controlling part 20 may apply (e.g., may transmit) the data control signal, the first driving voltage, the second driving voltage, and the gate control signal to the data driving part 30, the first power driving part 50, the second power driving part 60, and the scan driving part 40, respectively.

Each of the pixels PX may include a light emitting region and a circuit region. The light emitting region may include an organic light emitting display element. The circuit region may include at least one thin film transistor and/or at least one capacitor. The thin film transistor may be electrically coupled to (e.g., electrically connected to) the data line and the gate line. The circuit region may be provided to (e.g., may be configured to) drive the organic light emitting display element.

As illustrated in FIG. 2, the flexible display panel 100 may include a base substrate 110, at least one transistor, an insulation interlayer, a protection layer 190, a first electrode 200, a light emitting structure 210, the second electrode 220, and at least one capacitor.

In example embodiments, the base substrate 110 may include a flexible substrate. The base substrate 110 may include a transparent insulating material capable of supporting conductive patterns and layers stacked on each other. A buffer layer 112 may be provided on the base substrate 110.

At least one of a first and/or second transistor and at least one capacitor may be provided on the base substrate 110 in the circuit region of the flexible display panel 100. However, the number of transistors and the number of capacitors may not be limited thereto.

For example, the first transistor may include a first semiconductor pattern 120, a first gate electrode 140, a first source electrode 180, and a first drain electrode 182. A gate insulation layer 130 may be between the first semiconductor pattern 120 and the first gate electrode 140. The second transistor may include a second semiconductor pattern 122, a second gate electrode 142, a second source electrode 186, and a second drain electrode 188. The gate insulation layer 130 may be between the second semiconductor pattern 122 and the second gate electrode 142. The capacitor may include a first capacitor electrode and a second capacitor electrode. A portion of the second gate electrode 142 may be used (utilized) as the first capacitor electrode and a portion of a third gate electrode 152 may be used as the second capacitor electrode.

The transistor may be a thin film transistor having a top-gate structure. However, a structure of the thin film transistor included in the flexible display device may not be limited thereto. For example, the transistor may be a thin film transistor having a bottom-gate structure.

The first semiconductor pattern 120 and the second semiconductor pattern 122 may be provided on the buffer layer 112, and the gate insulation layer 130 may be provided on the buffer layer 112 and be over (e.g., cover) the first and second semiconductor patterns 120 and 122.

A first conductive pattern including the first gate electrode 140 and the second gate electrode 142 may be provided on the gate insulation layer 130. The first conductive pattern on the gate insulation layer 130 may further include the gate lines S1, S2, . . . Sn. The gate lines may extend in a first direction on the gate insulation layer 130. The gate electrode may be coupled to (e.g., connected to) the gate lines.

The insulation interlayer may include a first insulation interlayer 150 and a second insulation interlayer 160. The first insulation interlayer 150 may be provided on the gate insulation layer 130 and be over (e.g., cover) the first gate electrode 140 and the second gate electrode 142. The third gate electrode 152 may be provided on the first insulation interlayer 150 and overlap the second gate electrode 142. The second insulation interlayer 160 may be provided on the first insulation interlayer 150 and be over (e.g., cover) the third gate electrode 152.

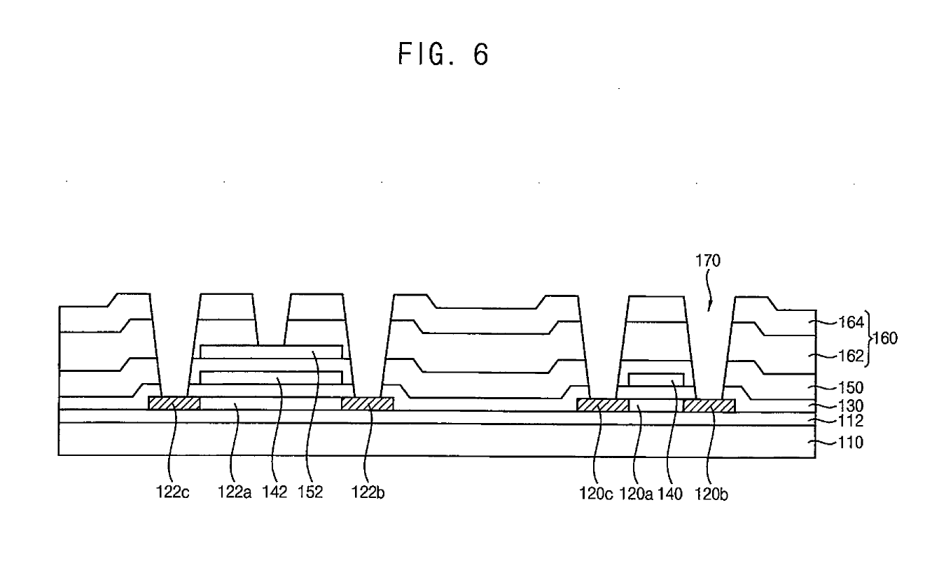

A second conductive pattern including the first source electrode 180, the second source electrode 186, the first drain electrode 182, the second drain electrode 186, and a connection electrode 184 may be provided on the insulation interlayer. The first and second source electrodes 180 and 186 may be coupled to (e.g., connected to) first and second source regions 120b and 122b through contact openings 170 (e.g., contact holes), respectively (see, e.g., FIG. 6). The first and second drain, electrodes 182 and 188 may be coupled to (e.g., connected to) first and second drain regions 120c and 122c through contact openings 170, respectively. The connection electrode 184 may be coupled to (e.g., connected to) the third gate electrode 152 through the contact openings 170.

The second conductive pattern may further include the data lines D1, D2, . . . Dm and the driving voltage lines G1, G2, . . . Gm. The data lines and the driving voltage lines may extend in a second direction that crosses (e.g., is substantially perpendicular to) the first direction and parallel with each other on the second insulation interlayer 160.

In this embodiment, the source electrode of the transistor may be coupled to (e.g., connected to) one or more of the data lines. The third gate electrode 152 may be coupled to (e.g., connected to) one or more of the driving voltage lines through the connection electrode 184.

The insulation interlayer may include a plurality of stress relief openings 166 that are formed at regions of the insulation interlayer exposed by the second conductive pattern. The stress relief opening 166 may be provided to penetrate (e.g., penetrate completely through) the second and first insulation interlayers 160 and 150. The openings 166 may expose at least a portion of the gate insulation layer 130, the first gate electrode 140, and the third gate electrode 152, respectively.

The insulation interlayer may have a multi-layered structure of inorganic layers. The inorganic layer may include silicon oxide, silicon nitride, silicon oxynitride, silicon carbonitride, etc.

The protection layer 190 may be over (e.g., may cover) the second conductive pattern and have a substantially flat upper surface. The protection layer 190 may partially or completely fill the stress relief openings 166.

When the flexible display panel 100 is bent, a stress may be exerted in the insulation interlayer having an inorganic material by a compressive or tensile force. The stress relief openings 166 may be provided in the insulation interlayer and filled with the protection layer 190 that includes an organic material. Accordingly, cracking or tearing may be prevented (or protected) from occurring in the insulation interlayer due to the stress. Thus, damages due to the stress in the flexible display device may be prevented to thereby improve electrical properties of the transistor and the capacitor.

The protection layer 190 may have an opening 192 which exposes at least a portion of the first drain electrode 182. The first electrode 200 may be provided on the protection layer 190 and be coupled to (e.g., connected to) the first drain electrode 182. A pixel defining layer 202 may be provided on the protection layer 190 and expose at least a portion of the first electrode 200. The light emitting structure 210 and the second electrode 220 may be provided (e.g., sequentially provided) on the first electrode 200.

Hereinafter, a method of manufacturing the flexible organic light emitting display device in FIG. 2 will be further explained.

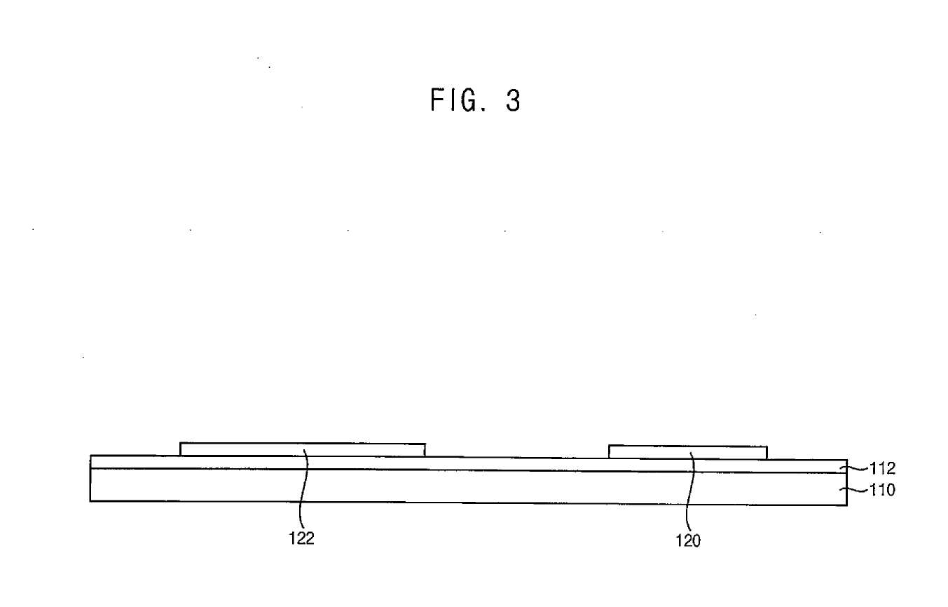

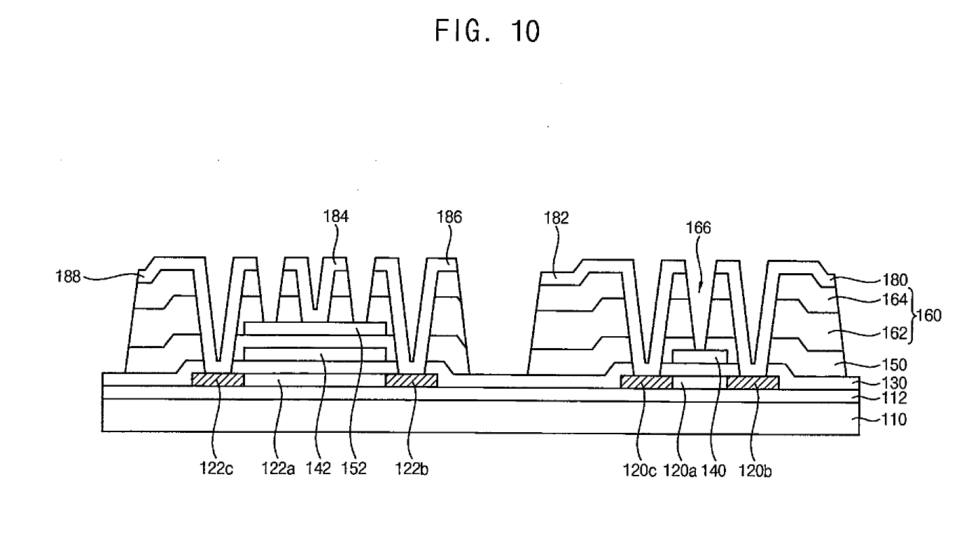

FIGS. 3 to 11 are cross-sectional views illustrating a method of manufacturing a flexible display device in accordance with example embodiments.

Referring to FIG. 3, a buffer layer 112 and first and second semiconductor patterns 120 and 122 may be formed on a base substrate 110.

The base substrate 110 may include a flexible substrate. For example, the base substrate 110 may include polyimide, polycarbonate, polyethylene, etc. The base substrate 110 may include a transparent insulating material capable of supporting conductive patterns and layers stacked on each other.

The buffer layer 112 may be formed on the base substrate 110. The buffer layer 112 may provide a flat surface (e.g., a planar surface) on an upper surface of the base substrate 110 and may prevent diffusion of moisture or impurities therethrough. The buffer layer 112 may include a silicon compound. For example, the buffer layer 112 may include silicon oxide, silicon nitride, silicon oxynitride, etc. The buffer layer 112 may be formed by a chemical vapor deposition process, a thermal oxidation process, a plasma enhanced chemical vapor deposition process, a high density plasma chemical vapor deposition process, a spin coating process, etc.

The buffer layer 112 may have a multi-layered structure of inorganic layers, (such as a silicon compound) stacked on each other, or a multi-layered structure of an organic layer and an inorganic layer stacked (e.g., alternately stacked) on each other.

Then, the first semiconductor pattern 120 and the second semiconductor pattern 122 may be formed on the buffer layer 112.

For example, a semiconductor layer may be formed on the buffer layer 112 and then patterned to form preliminary first and second semiconductor patterns. Then, a crystallization process may be performed on the preliminary first and second semiconductor patterns to form the first and second semiconductor patterns 120 and 122. The first and second semiconductor patterns 120 and 122 may include amorphous silicon, polysilicon, etc.

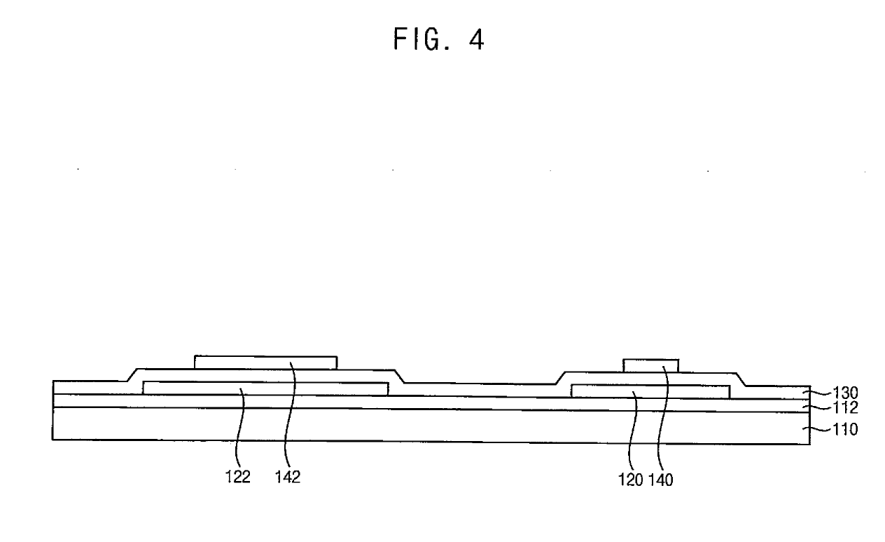

Referring to FIG. 4, after a gate insulation layer 130 is formed on the buffer layer 112 to cover the first and second semiconductor patterns 120 and 122, a first conductive pattern including a first gate electrode 140 and a second gate electrode 142 may be formed on the gate insulation layer 130.

First, the gate insulation layer 130 may be formed on the buffer layer 112. The gate insulation layer 130 may be formed using (utilizing or including) a silicon oxide, a metal oxide, etc. For example, the metal oxide for forming the gate insulation layer 130 may include hafnium oxide (HfOₓ), aluminum oxide (AlOₓ), zirconium oxide (ZrOₓ), titanium oxide (TiOₓ), tantalum oxide (TaOₓ), etc. These may be used alone or in a mixture thereof. The gate insulation layer 130 may be formed by a chemical vapor deposition process, a plasma enhanced chemical vapor deposition process, a high density plasma chemical vapor deposition process, a spin coating process, a sputtering process, a vacuum deposition process, etc.

Then, the first conductive pattern may be formed on the gate insulation layer 130.

For example, a first conductive layer may be formed on the gate insulation layer 130 and then patterned by an etching process to form the first conductive pattern including the first gate electrode 140 and the second gate electrode 142.

The first conductive layer may include aluminum (Al), chromium (Cr), nickel (Ni), molybdenum (Mo), tungsten (W), magnesium (Mg). These may be used alone or in an alloy thereof. The first gate electrode 140 and the second gate electrode 142 may have a single-layered structure or a multi-layered structure. The first conductive layer may be formed by a sputtering process, a chemical vapor deposition process, an atomic layer deposition process, etc.

The first conductive pattern on the gate insulation layer 130 may further include gate lines S1, S2, . . . Sn. The gate lines may extend in a first direction on the gate insulation layer 130. The gate electrode may be coupled to (e.g., connected to) one or more of the gate lines.

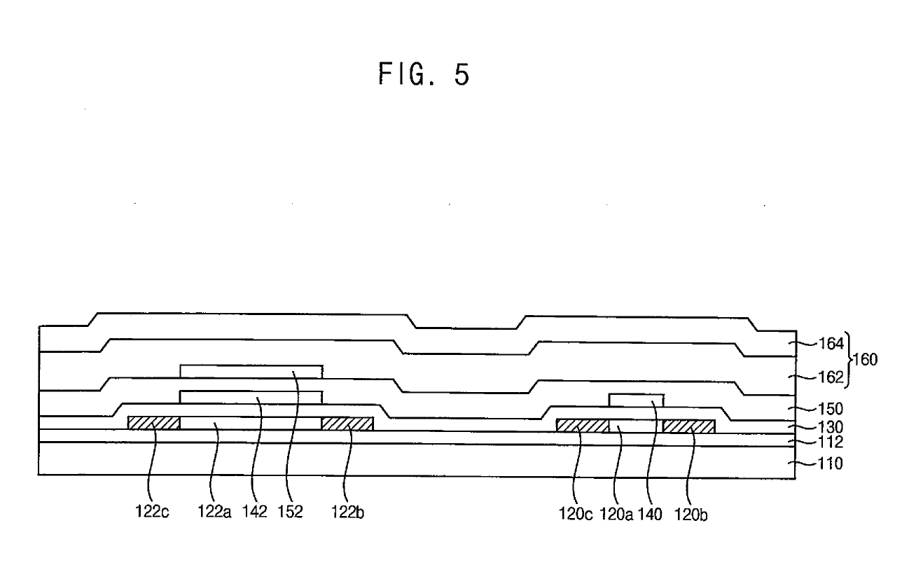

Referring to FIG. 5, after a first insulation interlayer 150 is formed on the gate insulation layer 130 to cover the first gate electrode 140 and the second gate electrode 150, a third gate electrode 152 may be formed on the first insulation interlayer 150 to overlap the second gate electrode 142. Then, a second insulation interlayer 160 may be formed on the first insulation interlayer 150 to cover the third gate electrode 152.

For example, first, impurities may be doped into the first and second semiconductor patterns 120 and 122 using (utilizing) the first gate electrode 140 and the second gate electrode 142 as masks. Accordingly, impurities may be doped in both sides of the first semiconductor pattern 120, to form a first channel region 120a, a first source region 120b, and a first drain region 120c. Impurities may be doped in both sides of the second semiconductor pattern 122, to form a second channel region 122a, a second source region 122b, and a second drain region 122c.

Then, the first insulation interlayer 150 may be formed on the gate insulation layer 130 to cover the first gate electrode 140 and the second gate electrode 142.

The first insulation interlayer 150 may be formed using a silicon compound. For example, the first insulation interlayer 150 may be formed using silicon oxide, silicon nitride, silicon oxynitride, silicon carbonitride, etc. These may be used alone or in a combination thereof. The first insulation interlayer 150 may have a multi-layered structure with (or including) the above inorganic layers. The first insulation interlayer 150 may be formed by a spin coating process, a chemical vapor deposition process, a plasma enhanced chemical vapor deposition process, a high density plasma chemical vapor deposition process, etc.

Then, the third gate electrode 152 may be formed on the first insulation interlayer 150 to overlap the second gate electrode 142. Accordingly, the first insulation interlayer 150 may be between the second gate electrode 142 and the third gate electrode 152. A portion of the second gate electrode 142 may be used as a first capacitor electrode, and a portion of the third gate electrode 152 may be used as a second capacitor electrode.

Then, the second insulation interlayer 160 may be formed on the first insulation interlayer 150 to cover the third gate electrode 152.

For example, the second insulation interlayer 160 may be formed using silicon oxide, silicon nitride, silicon oxynitride, silicon carbonitride, etc. These may be used alone or in a combination thereof.

The second insulation interlayer 160 may have a multi-layered structure including the above inorganic layers. The second insulation interlayer 160 may include a lower second insulation interlayer 162 and an upper second insulation interlayer 164 having inorganic layers different from each other. The second insulation interlayer 160 may include a material the same as or different from the first insulation interlayer 150.

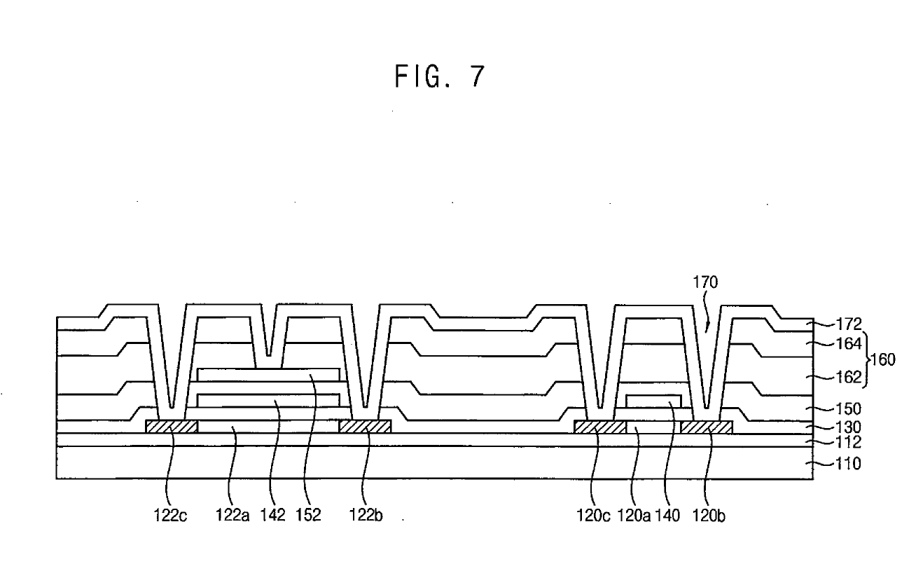

Referring to FIGS. 6 and 7, after contact openings 170 (e.g., contact holes) are formed in the second and first insulation interlayers 160 and 150, a second conductive layer 172 may be formed on the second insulation interlayer 160 to fill the contact openings 170.

For example, the second and first insulation interlayers 160 and 150 and the gate insulation layer 130 may be etched (e.g., partially etched) to form the contact openings 170 that expose the first and second source regions 120b and 122b, the first and second drain regions 120c and 122c, and the third gate electrode 152.

Then, the second conductive layer 172 may be formed on the second insulation interlayer 160 to partially fill the contact openings 170 (e.g., to substantially coat a surface of the contact openings 170).

The second conductive layer 172 may include aluminum (Al), chrome (Cr), nickel (Ni), molybdenum (Mo), tungsten (W), and/or magnesium (Mg). These may be used alone or in an alloy thereof. The second conductive layer 172 may have a single-layered structure or a multi-layered structure. The second conductive layer 172 may be formed by a sputtering process, a chemical vapor deposition process, an atomic layer deposition process, etc.

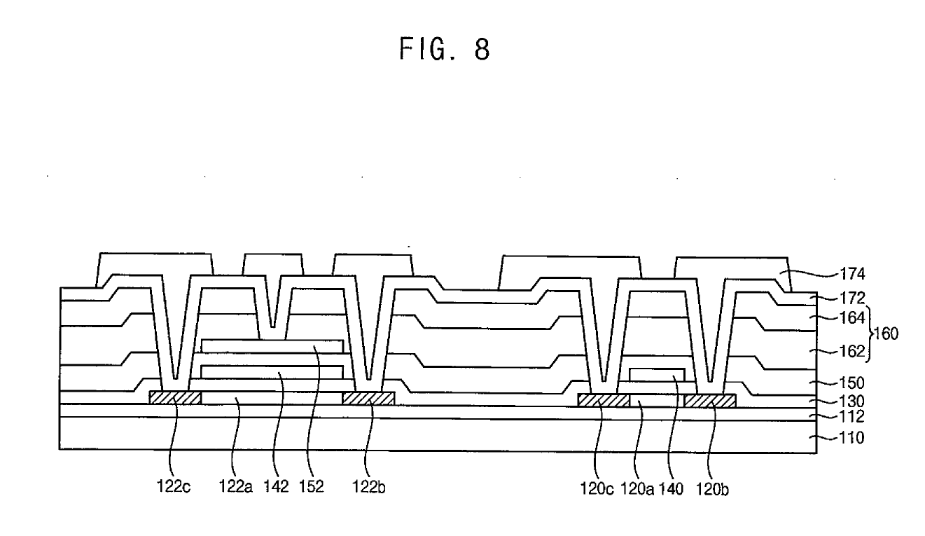

Referring to FIGS. 8 to 10, after the second conductive layer 172 is patterned to form a second conductive pattern including a first source electrode 180, a second source electrode 186, a first drain electrode 182, a second drain electrode 188, and a connection electrode 184, stress relief openings 166 may be formed at portions of the second insulation interlayer 160 exposed by the second conductive pattern.

For example, a photoresist pattern 174 may be formed on the second conductive layer 172, and then, the second conductive layer 172 may be etched utilizing the photoresist pattern 174 as an etching mask to form the second conductive pattern. The second conductive pattern may be formed by a wet etching process or a dry etching process.

The first and second source electrodes 180 and 186 and the first and second drain electrodes 182 and 188 may be formed to provide first and second transistors on the base substrate 110. The first transistor may include the first semiconductor pattern 120, the first gate electrode 140, the first source electrode 180, and the first drain electrode 182. The second transistor may include the second semiconductor pattern 122, the second gate electrode 142, the second source electrode 186, and the second drain electrode 188.

The first and second source electrodes 180 and 186 may be coupled to (e.g., connected to) the first and second source regions 120b and 122b through the contact openings 170, respectively. The first and second drain electrodes 182 and 188 may be coupled to (e.g., connected to) the first and second drain regions 120c and 122c through the contact openings 170, respectively. The connection electrode 184 may be coupled to (e.g., connected to) the third gate electrode 152 through one of the contact openings 170.

The second conductive pattern on the second insulation interlayer 160 may further include data lines D1, D2, . . . Dm and driving voltage lines G1, G2, . . . Gm. The data lines and the driving voltage lines may extend in a second direction that crosses (e.g., is substantially perpendicular to) the first direction and parallel with each other on the second insulation interlayer 160.

In this embodiment, the source electrode of the transistor may be coupled to (e.g., connected to) one or more of the data lines. The third gate electrode 152 may be coupled to (e.g., connected to) one or more of the driving voltage lines through the connection electrode 184.

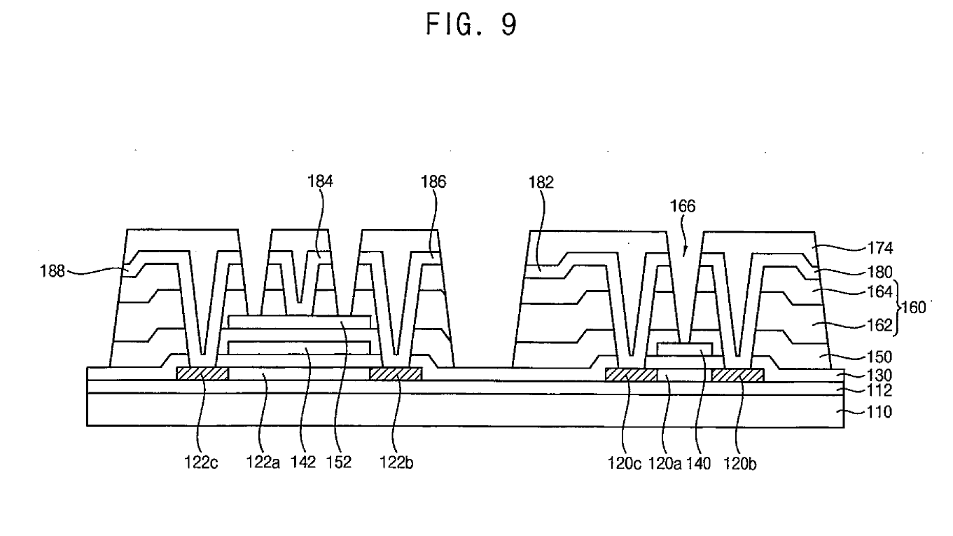

Then, as illustrated in FIG. 9, portions of the second and first insulation interlayers 160 and 150 exposed by the second conductive pattern may be etched to form the stress relief openings 166.

For example, the second and first insulation interlayers 160 and 150 may be partially etched by a dry etching process. When the second conductive pattern is formed by a dry etching process, the second and first insulation interlayers 160 and 150 may be partially removed (e.g., portions of the second and first insulation interlayers 160 and 150 may be etched) utilizing the photoresist pattern 174 as an etching mask to form the openings 166. Then, the photoresist pattern 174 may be removed from the base substrate 110.

During the etching process, the gate insulation layer 130, the first gate electrode 140, and the third gate electrode 152 may be utilized as or may be an etching stop layer. Accordingly, the openings 166 may expose the gate insulation layer 130, the first gate electrode 140, and the third gate electrode 152, respectively.

When the second conductive pattern is formed by a wet etching process, the photoresist pattern 174 is removed and then the second and first insulation interlayers 160 and 150 may be partially removed (e.g., portions of the second and first insulation interlayers 160 and 150 may be removed) utilizing the second conductive pattern as an etching mask to form the openings 166.

Thus, the openings 166 (e.g., the self-aligned openings) may be formed in the insulation interlayer (e.g., in the first and second insulation interlayers 150 and 160) by the second conductive pattern.

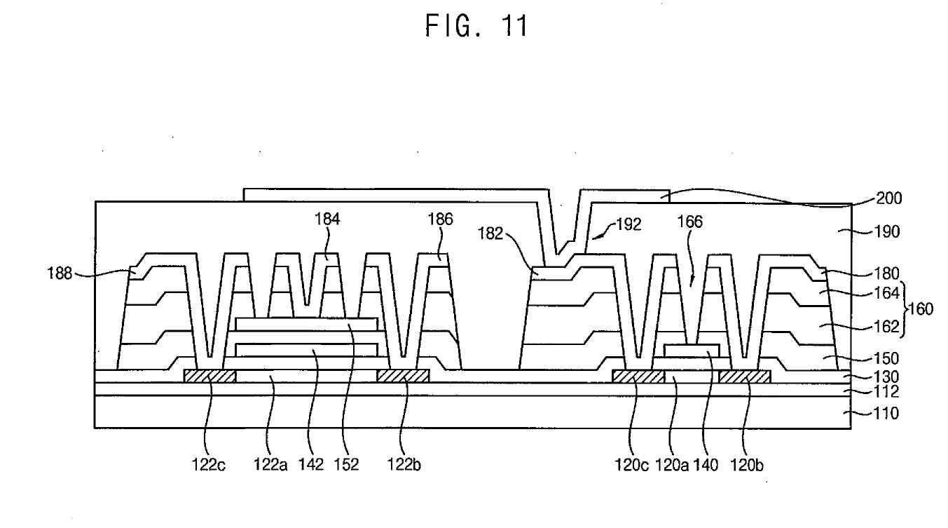

Referring to FIG. 11, the protection layer 190 may be formed on the second insulation interlayer 160 to cover the second conductive pattern.

The protection layer 190 may cover the first and second source electrodes 180 and 186, the first and second drain electrodes 182 and 188, and the connection electrode 184 and have a substantially flat or planar upper surface. The protection layer 190 may partially or completely fill the stress relief openings 166.

The protection layer 190 may be formed using a transparent insulating material and/or a metal compound. For example, the protection layer 190 may include a photoresist, an acryl-based polymer, a polyimide-based polymer, a polyamide-based polymer, a siloxane-based polymer, and/or a polymer containing one or more of a photosensitive carboxyl acrylic group′, a novolak resin, an alkali-soluble resin, silicon oxide, silicon nitride, silicon oxynitride, silicon oxycarbide, silicon carbonitride, aluminum oxide, titanium oxide, tantalum oxide, magnesium oxide, zinc oxide, hafnium oxide, zirconium oxide, and/or the like. These may be used alone or in a combination thereof. The protection layer 190 may be formed by a spin coating process, a printing process, a sputtering process, a chemical vapor deposition process, an atomic layer deposition process, a plasma enhanced chemical vapor deposition process, a high density plasma chemical vapor deposition process, a vacuum evaporation process, and the like.

Then, after the protection layer 190 is partially etched to form an opening that exposes the first drain electrode 182, a third conductive layer may be formed on the protection layer 190 to fill the opening 192.

The third conductive layer may be formed by a sputtering process, a chemical vapor deposition process, an atomic layer deposition process, a printing process, a vacuum deposition process, a pulse laser deposition process, etc.

Then, the third conductive layer may be patterned by an etching process to form a first electrode 200 at a pixel region.

Referring again to FIGS. 1 and 2, a light emitting structure 210 and a second electrode 220 may be formed on the first electrode 200.

The pixel defining layer 202 may be formed on the protection layer 190. The pixel defining layer 202 may be formed using an organic material and/or an inorganic material. The pixel defining layer 202 may be formed utilizing a photoresist, a polyacryl-based resin, a polyimide-based resin, an acryl-based resin, a silicon compound, etc.

The pixel defining layer 202 may be partially etched to form an opening that exposes the first electrode 200. The light emitting region may be defined at the pixel region of the organic light emitting display device by the opening in the pixel defining layer 202. That is, a portion of the pixel region where the opening of the pixel defining layer 202 is located may correspond to the light emitting region, and the remaining portion of the pixel region may correspond to a non-light emitting region. An upper width of the opening of the pixel defining region 202 may be greater than a lower width of the opening of the pixel defining region 202. The opening of the pixel defining layer 202 may have an inclined sidewall with an angle (e.g., with a predetermined angle).

The light emitting structure 210 may be formed on the portion of the first electrode 200 exposed by the opening in the pixel defining layer 202. The light emitting structure 210 may include a light emitting layer (EL), a hole injection layer (HIL), a hole transport layer (HTL), an electron transport layer (ETL), an electron injection layer (EIL), etc. In example embodiments, the light emitting layer of the light emitting structure 210 may be formed utilizing light emitting materials for generating different colors of light, such as a red color light, a green color light, and a blue color light in accordance with the pixels of the organic light emitting display device. Alternatively, the light emitting layer of the light emitting structure 210 may have a multi-layered structure for generating a white color light by successively depositing a plurality of light emitting materials for generating different colors of light such as a red color light, a green color light, and a blue color light.

The light emitting structure 210 may make contact with the first electrode 200 and the pixel defining layer 202. A lower face of the light emitting structure 210 may contact the first electrode 200, and a lateral portion of the light emitting structure 210 may make contact with the pixel defining layer 202. A sidewall of the light emitting structure 210 may have an angle of inclination substantially the same as or substantially similar to that of the sidewall of the opening of the pixel defining layer 202.

Then, the second electrode 220, acting as a common electrode shared by the pixels, may be formed on the pixel defining layer 202 and the light emitting structure 210 to form an organic light emitting display panel.

The second electrode 220 may be formed using a metal, an alloy, a metal nitride, a transparent conductive material, a conductive metal compound, etc. The second electrode 220 may be formed by a sputtering process, a chemical vapor deposition process, an atomic layer deposition process, a printing process, a vacuum evaporation process, a pulsed laser deposition process, a printing process, etc.

A sealing layer 230 may be formed on the second electrode 220. The sealing layer 230 may protect underlying structures and serve as a sealing member for the display device. For example, the sealing layer 230 may include a transparent insulating material such as glass, transparent plastic, transparent ceramic, etc.

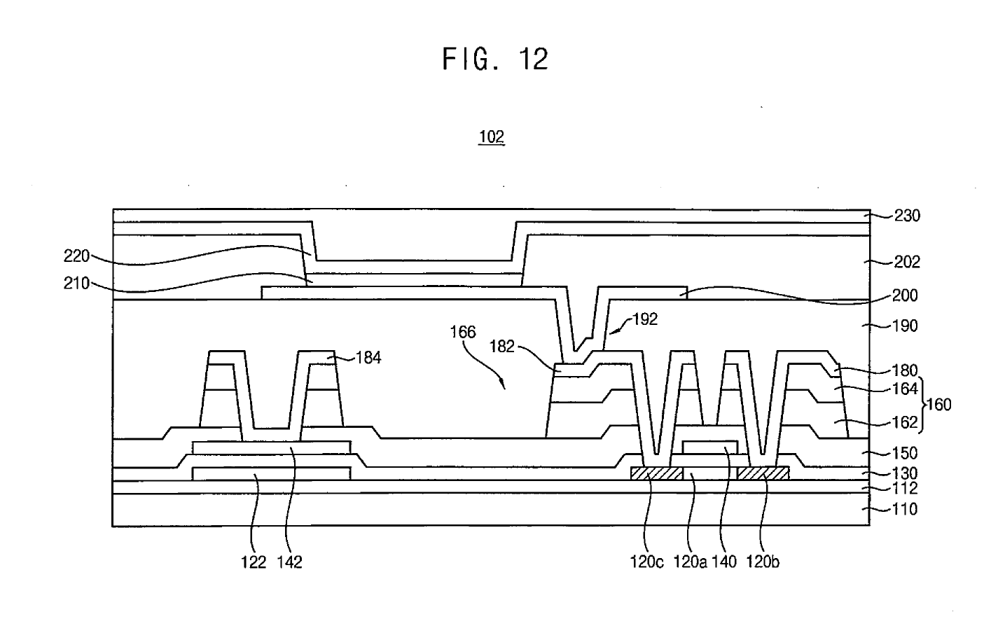

FIG. 12 is a cross-sectional view illustrating a flexible display device in accordance with example embodiments. The flexible display device is substantially the same as the flexible display device described with reference to FIG. 2, except a structure of a capacitor and a depth of a stress relief opening. Thus, the same or like reference numerals will be used to refer to as the same or like elements, and any repetitive explanation concerning the above elements may be omitted.

Referring to FIG. 12, a flexible display panel 102 may include a base substrate 110, at least one transistor, an insulation interlayer, a protection layer 190, a first electrode 200, a light emitting structure 210, a second electrode 220, and at least one capacitor.

In example embodiments, the base substrate 110 may include a flexible substrate. The base substrate 110 may include a transparent insulating material capable of supporting conductive patterns and layers stacked on each other. A buffer layer 112 may be provided on the base substrate 110.

At least one transistor and at least one capacitor may be provided on the base substrate 110 at a circuit region of the flexible display panel 100. However, the number of the transistors and the number of the capacitors may not be limited thereto.

For example, the transistor may include a semiconductor pattern 120, a gate electrode 140, a source electrode 180, and a drain electrode 182. A gate insulation layer 130 may be between the first semiconductor pattern 120 and the first gate electrode 140. The capacitor may include a first capacitor electrode 122 and a second capacitor electrode 142.

The semiconductor pattern 120 and the first capacitor electrode 122 may be provided on the buffer layer 112, and the gate insulation layer 130 may be provided on the buffer layer 112 to cover the semiconductor pattern 120 and the first capacitor electrode 122.

A first conductive pattern including the gate electrode 140 and the second capacitor electrode 142 may be provided on the gate insulation layer 130. The first conductive pattern on the gate insulation layer 130 may further include the gate lines S1, S2, . . . Sn. The gate lines may extend in a first direction on the gate insulation layer 130. The gate electrode may be coupled to (e.g., connected to) one or more of the gate lines.

The insulation interlayer may include a first insulation interlayer 150 and a second insulation interlayer 160. The first insulation interlayer 150 may be provided on the gate insulation layer 130 to cover the gate electrode 140 and the second capacitor electrode 142. The second insulation interlayer 160 may be provided on the first insulation interlayer 150.

A second conductive pattern including the source electrode 180, the drain electrode 182, and a connection electrode 184 may be provided on the insulation interlayer. The source electrode 180 may be coupled to (e.g., connected to) a source region 120b through a contact opening 170 (e.g., a contact hole). The drain electrode 182 may be coupled to (e.g., connected to) a drain region 120c through another contact opening 170. The connection electrode 184 may be coupled to (e.g., connected to) the second capacitor electrode 142 through another contact opening 170.

The second conductive pattern may further include data lines D1, D2, . . . Dm and driving voltage lines G1, G2, . . . Gm. The data lines and the driving voltage lines may extend in a second direction that crosses (e.g., is substantially perpendicular to) the first direction and parallel with each other on the second insulation interlayer 160.

In this embodiment, the source electrode of the transistor may be coupled to (e.g., connected to) one or more of the data lines. The second capacitor electrode 142 may be coupled to (e.g., connected to) one or more of the driving voltage lines through the connection electrode 184.

The insulation interlayer may include a plurality of stress relief openings 166 that are formed at regions of the insulation interlayer exposed by the second conductive pattern. The stress relief opening 166 may be provided to penetrate (e.g., completely penetrate) the second insulation interlayer 160. The openings 166 may expose the first insulation interlayer 150.

The insulation interlayer may have a multi-layered structure of inorganic layers. The inorganic layer may include silicon oxide, silicon nitride, silicon oxynitride, silicon carbonitride, etc.

The protection layer 190 may cover the second conductive pattern and have a substantially flat or planar upper surface. The protection layer 190 may partially or completely fill the stress relief openings 166.

When the flexible display device 100 is bent, a stress may be generated in the insulation interlayer including an inorganic material by a compressive or tensile force. The stress relief openings 166 may be provided in the insulation interlayer and filled (e.g., filled up) with the protection layer including an organic material. Accordingly, cracking or tearing may be prevented from occurring in the insulation interlayer due to the stress.

The protection layer 190 may have an opening 192 which exposes the drain electrode 182. The first electrode 200 may be provided on the protection layer 190 and be coupled to (e.g., connected to) the drain electrode 182. A pixel defining layer 202 may be provided on the protection layer 190 and may expose the first electrode 200. The light emitting structure 210 and the second electrode 220 may be provided (e.g., sequentially provided) on the first electrode 200.

Hereinafter, a method of manufacturing the flexible organic light emitting display device in FIG. 12 will be explained.

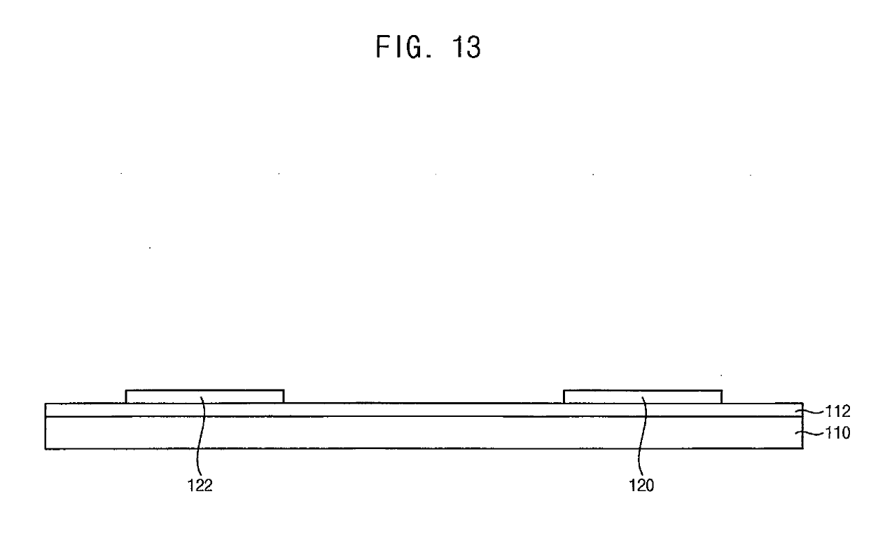

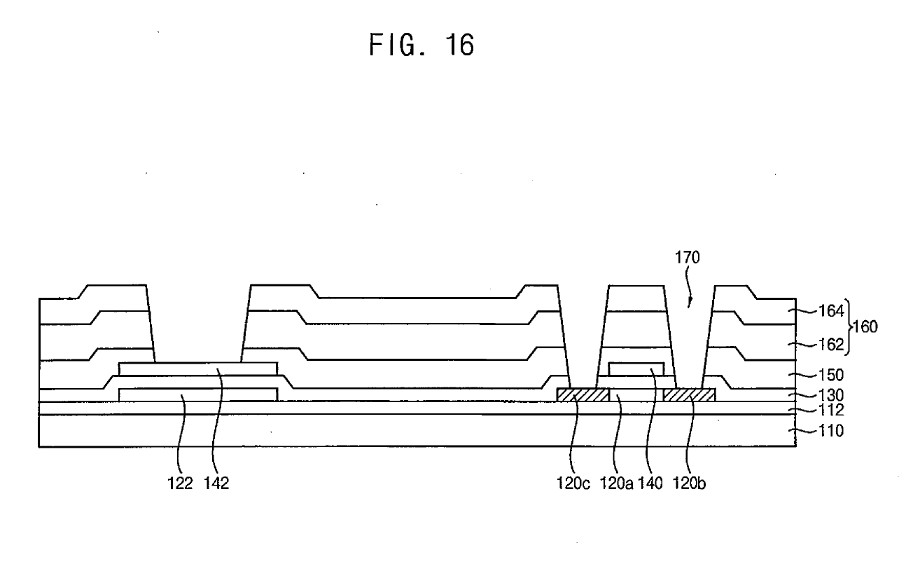

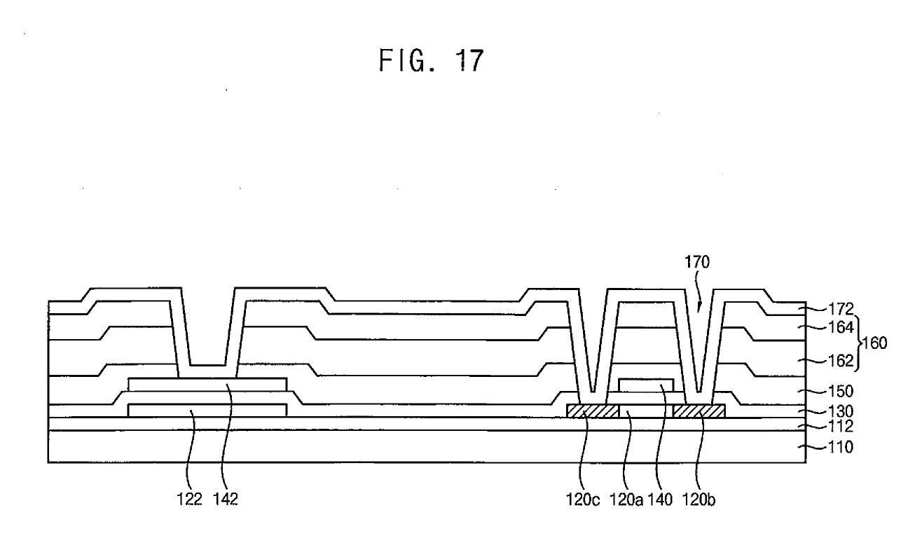

FIGS. 13 to 21 are cross-sectional views illustrating a method of manufacturing a flexible display device in accordance with example embodiments.

Referring to FIG. 13, after a buffer layer 112 is formed on a base substrate 110, a semiconductor pattern 120 and a first capacitor electrode 122 may be formed on the base substrate 110.

The base substrate 110 may include a flexible substrate. For example, the base substrate 110 may include polyimide, polycarbonate, polyethylene, etc.

The buffer layer 112 may be formed on the base substrate 110. The buffer layer 112 may include a silicon compound. The buffer layer 112 may have a multi-layered structure of inorganic layers, such as a silicon compound, stacked on each other or an organic layer and an inorganic layer stacked (e.g., alternately stacked) on each other.

Then, the semiconductor pattern 120 and the first capacitor electrode 122 may be formed on the buffer layer 112. The semiconductor pattern 120 and the first capacitor electrode 122 may include amorphous silicon, polysilicon, etc.

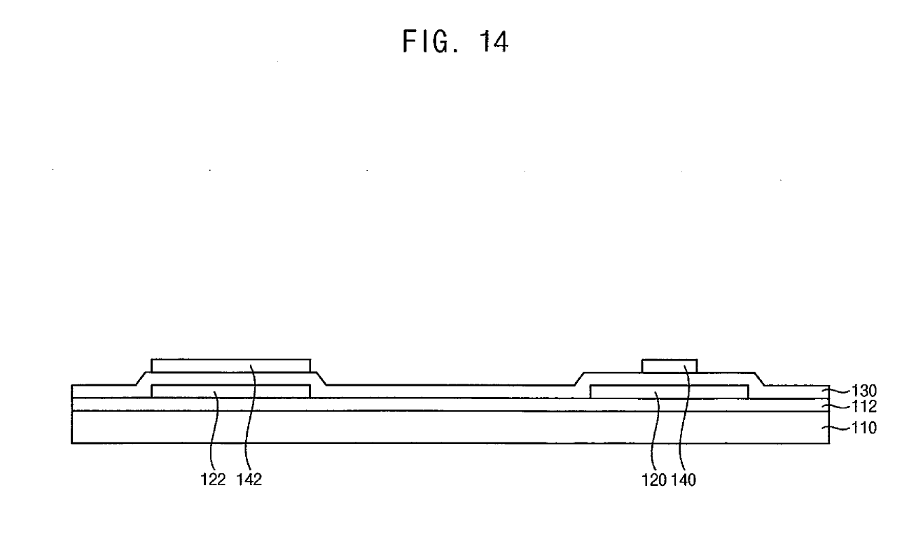

Referring to FIG. 14, after a gate insulation layer 130 is formed on the buffer layer 112 to cover the semiconductor pattern 120 and the first capacitor electrode 122, a first conductive pattern including a gate electrode 140 and a second capacitor electrode 142 may be formed on the gate insulation layer 130.

First, the gate insulation layer 130 may be formed on the buffer layer 112. The gate insulation layer 130 may be formed using silicon oxide, a metal oxide, etc.

Then, the first conductive pattern may be formed on the gate insulation layer 130. For example, a first conductive layer may be formed on the gate insulation layer 130 and then patterned by an etching process to form the first conductive pattern including the gate electrode 140 and the second capacitor electrode 142.

The first conductive layer may include aluminum (Al), chromium (Cr), nickel (Ni), molybdenum (Mo), tungsten (W), and/or magnesium (Mg). These may be used alone or in an alloy thereof. The gate electrode 140 and the second capacitor electrode 142 may have a single-layered structure or a multi-layered structure.

As the second capacitor electrode 142 is formed, a capacitor including the first capacitor electrode 122 and the second capacitor electrode 142 may be formed on the base substrate 110. The gate insulation layer 130 may be between the first capacitor electrode 122 and the second capacitor electrode 142.

The first conductive pattern on the gate insulation layer 130 may further include gate lines S1, S2, . . . Sn. The gate lines may extend in a first direction on the gate insulation layer 130. The gate electrode may be coupled to (e.g., connected to) one or more of the gate lines.

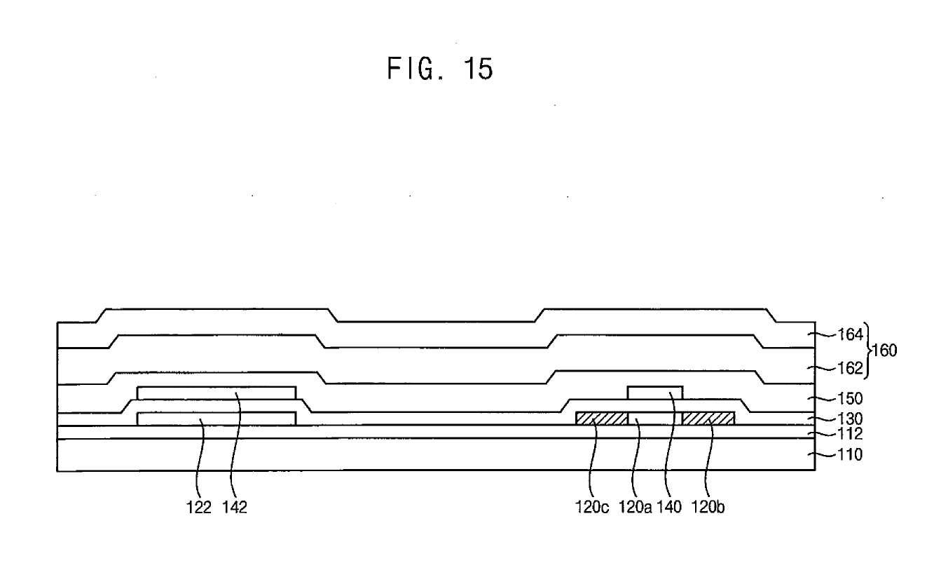

Referring to FIG. 15, after a first insulation interlayer 150 is formed on the gate insulation layer 130 to cover the gate electrode 140 and the second capacitor electrode 142, a second insulation interlayer 160 may be formed on the first insulation interlayer 150.

For example, first, impurities may be doped into the semiconductor pattern 120 using the gate electrode 140 as a mask. Accordingly, impurities may be doped in both sides of the semiconductor pattern 120 to form a channel region 120a, a source region 120b, and a drain region 120c.

Then, the first and second insulation interlayers 150 and 160 may be formed (e.g., sequentially formed) on the gate insulation layer 130 to cover the gate electrode 140 and the second capacitor electrode 142.

The first insulation interlayer 150 may be formed using a silicon compound. For example, the first insulation interlayer 150 may be formed using silicon oxide, silicon nitride, silicon oxynitride, silicon carbonitride, etc. These may be used alone or in a combination thereof. The first insulation interlayer 150 may have a multi-layered structure including the above inorganic layers.

The second insulation interlayer 160 may be formed using silicon oxide, silicon nitride, silicon oxynitride, silicon carbonitride, etc. These may be used alone or in a combination thereof.

The second insulation interlayer 160 may have a multi-layered structure including the above inorganic layers. The second insulation interlayer 160 may include a lower second insulation interlayer 162 and an upper second insulation interlayer 164 that include (or are formed with) different inorganic layers from each other. The second insulation interlayer 160 may include a material the same as or different from the first insulation interlayer 150.

Referring to FIGS. 6 and 7, after contact openings 170 (e.g., contact holes) are formed in the second and first insulation interlayers 160 and 150, a second conductive layer 172 may be formed on the second insulation interlayer 160 to fill the contact openings 170.

For example, the second and first insulation interlayers 160 and 150 and the gate insulation layer 130 may be partially etched (e.g., portions of the second and first insulation interlayers 160 and 150 may be etched) to form the contact openings 170 that expose the source region 120b, the drain region 120c, and the second capacitor electrode 142. Then, the second conductive layer 172 may be formed on the second insulation interlayer 160 to partially fill the contact openings 170.

The second conductive layer may include aluminum (Al), chromium (Cr), nickel (Ni), molybdenum (Mo), tungsten (W), magnesium (Mg). These may be used alone or in an alloy thereof. The second conductive layer may have a single-layered structure or a multi-layered structure.

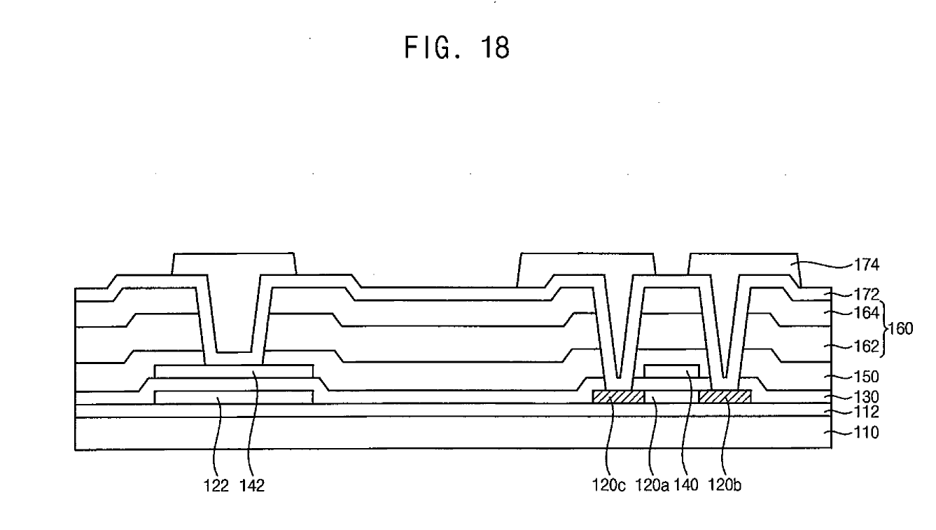

Referring to FIGS. 18 to 20, after the second conductive layer 172 is patterned to form a second conductive pattern including a source electrode 180, a drain electrode 182, and a connection electrode 184, stress relief openings 166 may be formed at portions of the second insulation interlayer 160 exposed by the second conductive pattern.

For example, a photoresist pattern 174 may be formed on the second conductive layer 172, and then, the second conductive layer 172 may be etched using the photoresist pattern 174 as an etching mask to form the second conductive pattern. The second conductive pattern may be formed by a wet etching process or a dry etching process.

The source electrode 180 and the drain electrode 182 may be formed to provide a transistor on the base substrate 110. The transistor may include the semiconductor pattern 120, the gate electrode 140, the source electrode 180, and the drain electrode 182.

The source electrode 180 may be coupled to (e.g., connected to) the source region 120b through one of the contact openings 170. The drain electrode 182 may be coupled to (e.g., connected to) the drain region 120c through one of the contact openings 170. The connection electrode 184 may be coupled to (e.g., connected to) the second capacitor electrode 142 through one of the contact openings 170.

The second conductive pattern on the second insulation interlayer 160 may further include data lines D1, D2, . . . Dm and driving voltage lines G1, G2, . . . Gm. The data lines and the driving voltage lines may extend in a second direction that crosses (e.g., is substantially perpendicular to) the first direction and parallel with each other on the second insulation interlayer 160.

In this embodiment, the source electrode of the transistor may be coupled to (e.g., connected to) one or more of the data lines. The second capacitor electrode 142 may be coupled to (e.g., connected to) one or more of the driving voltage lines through the connection electrode 184.

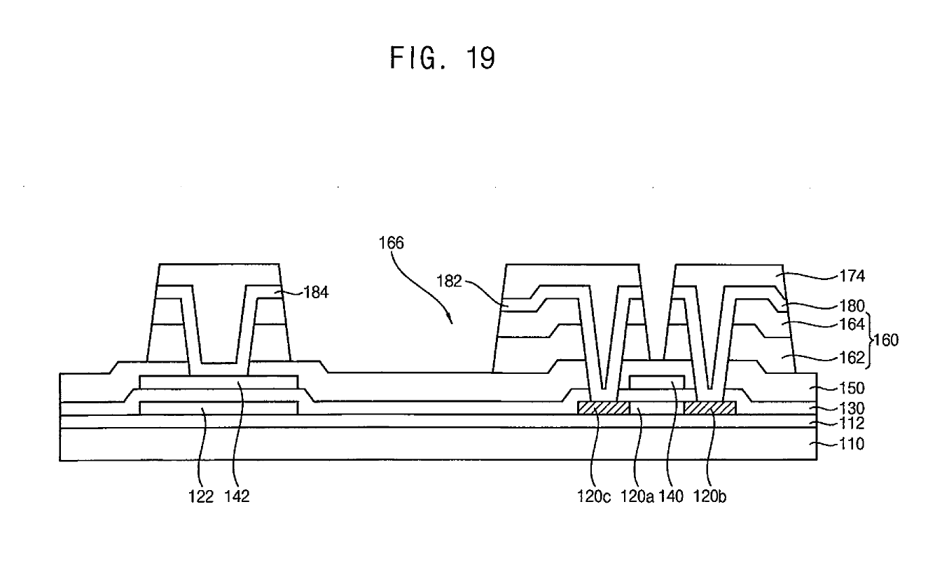

Then, as illustrated in FIG. 19, portions of the second insulation interlayer 160 exposed by the second conductive pattern may be etched to form stress relief openings 166.

For example, the second insulation interlayer 160 may be partially etched (e.g., a portion of second insulation interlayer 160 may be etched) by a dry etching process. When the second conductive pattern is formed by a dry etching process, the second insulation interlayer 160 may be partially removed using the photoresist pattern 174 as an etching mask to form the openings 166. Then, the photoresist pattern 174 may be removed from the base substrate 110.

During the etching process, the first insulation interlayer 150, the first gate electrode 140, and the third gate electrode 152 may be used as an etching stop layer. Accordingly, the openings 166 may expose the first insulation interlayer 150. The depth of the opening 166 may be determined in consideration of a material of the insulation interlayer, bending or warpage of the flexible display panel, etc.

When the second conductive pattern is formed by a wet etching process, the photoresist pattern 174 is removed and then the second insulation interlayer 160 may be partially removed using the second conductive pattern as an etching mask to form the openings 166.

Thus, the openings 166 (e.g., the self-aligned openings) may be formed in the insulation interlayer by the second conductive pattern.

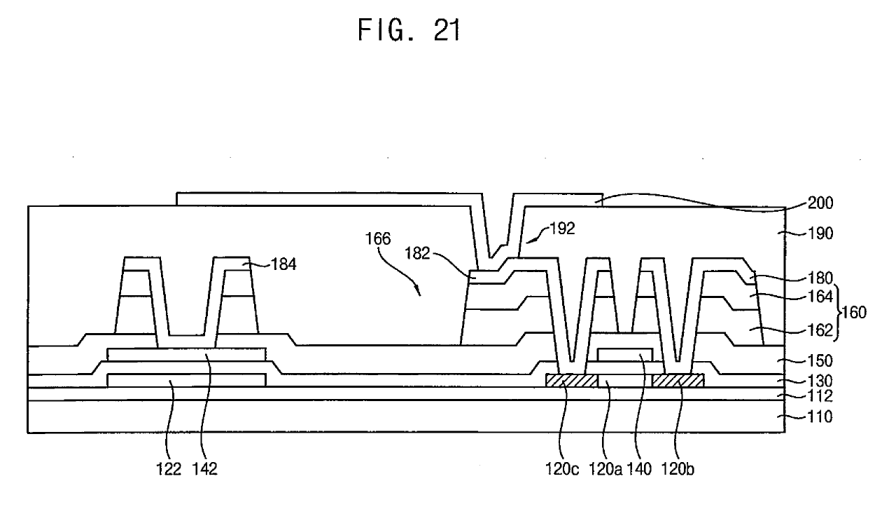

Referring to FIG. 21, the protection layer 190 may be formed on the second insulation interlayer 160 to cover the second conductive pattern.

The protection layer 190 may cover the source electrode 180, the drain electrode 182, and the connection electrode 184 and have a substantially flat or planar upper surface. The protection layer 190 may partially or completely fill the stress relief openings 166.

The protection layer 190 may be formed using a transparent insulating material and/or a metal compound. For example, the protection layer 190 may include a photoresist, an acryl-based polymer, a polyimide-based polymer, a polyamide-based polymer, a siloxane-based polymer, a polymer containing one or more of a photosensitive carboxyl acrylic group, a novolak resin, an alkali-soluble resin, silicon oxide, silicon nitride, silicon oxynitride, silicon oxycarbide, silicon carbonitride, aluminum oxide, titanium oxide, tantalum oxide, magnesium oxide, zinc oxide, hafnium oxide, zirconium oxide, and/or the like. These may be used alone or in a combination thereof.

Then, after the protection layer 190 is partially etched to form an opening that exposes the drain electrode 182, a third conductive layer may be formed on the protection layer 190 to fill the opening 192. Then, the third conductive layer may be patterned by an etching process to form a first electrode 200 at a pixel region.

Referring again to FIG. 12, a light emitting structure 210 and a second electrode 220 may be formed on the first electrode 200.

The light emitting structure 210 may include a light emitting layer (EL), a hole injection layer (HIL), a hole transport layer (HTL), an electron transport layer (ETL), an electron injection layer (EIL), etc.

The second electrode 220 may be formed using a metal, an alloy, a metal nitride, a transparent conductive material, a conductive metal compound, etc.

A sealing layer 230 may be formed on the second electrode 220. The sealing layer 230 may protect underlying structures and serve as a sealing member for the display device. For example, the sealing layer 230 may include a transparent insulating material such as glass, transparent plastic, transparent ceramic, etc.

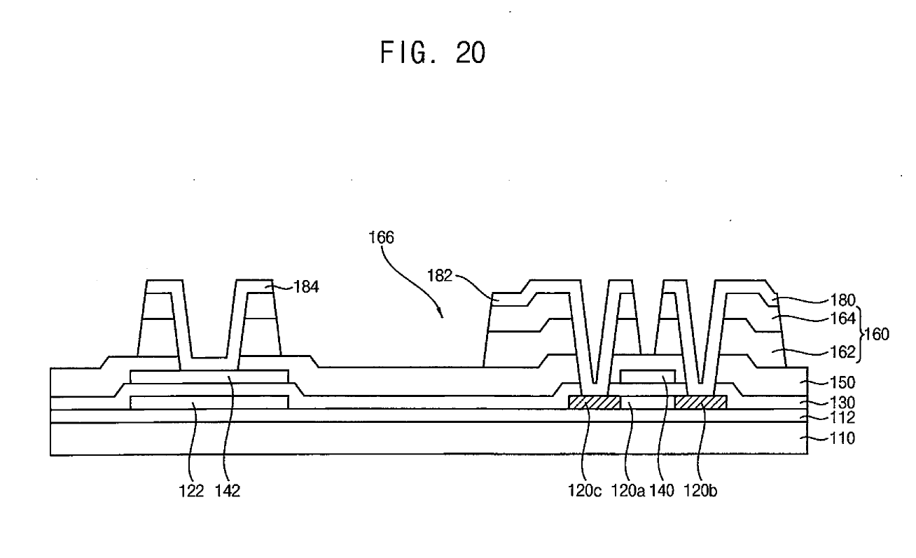

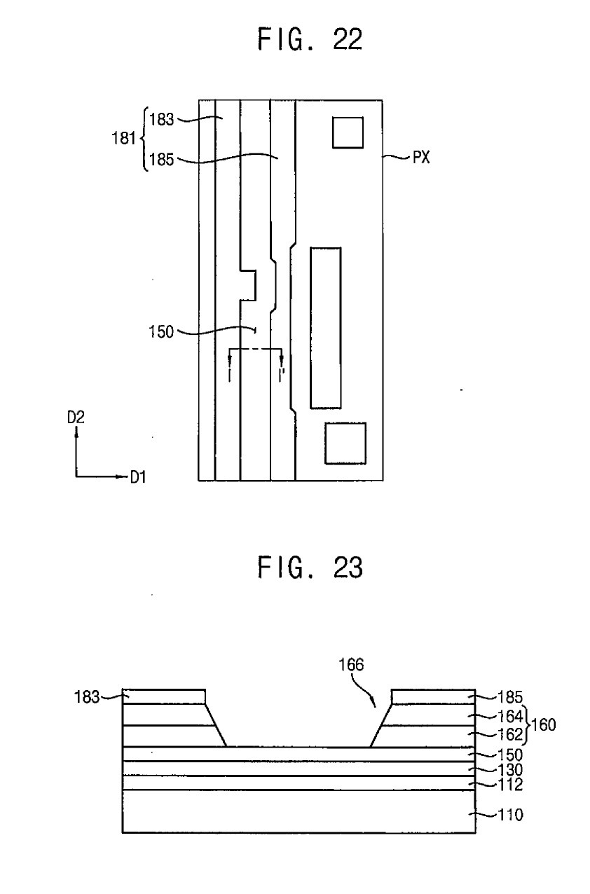

FIG. 22 is a plan view illustrating the second conductive pattern shown in FIG. 20. FIG. 23 is a cross-sectional view taken along the line I-I′ in FIG. 22.

Referring to FIGS. 22 and 23, a second conductive pattern 181 may include a data line 183, a driving voltage line 185, and connection lines. The data line 183 and the driving voltage line 185 may extend in a second direction D2 that crosses (e.g., is substantially perpendicular to) a first direction D1 and may be parallel with each other on a second insulation interlayer 160.

A stress relief opening 166 may be formed in the second insulation interlayer 160 corresponding to a position where the second insulation interlayer 160 is exposed by the data line 183 and the driving voltage line 185. The stress relief opening 166 may be self-aligned due to (or defined by) the second conductive pattern 181 (e.g., defined by the data line 183 and the driving voltage line 185).

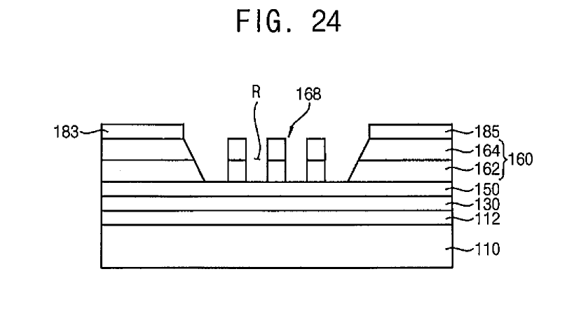

FIG. 24 is a cross-sectional view illustrating a stress relief opening in accordance with another example embodiment. FIG. 24 is a cross-sectional view taken along the line I-I′ in FIG. 22.

Referring to FIG. 24, a plurality of insulation interlayer patterns 168 may be formed in a stress relief opening 166. The insulation interlayer patterns 168 may be spaced from (e.g., spaced apart from) each other to define a plurality of recesses R therebetween. The recesses R may extend in a direction according to extending directions of the insulation interlayer patterns 168. The recesses R may extend in a first direction or a second direction.

For example, after a photoresist pattern having a plurality of slits is formed on the insulation interlayer, the insulation interlayer may be patterned using the photoresist pattern as an etching mask to from the insulation interlayer patterns 168.

The foregoing is illustrative of example embodiments and is not to be construed as limiting thereof. Although a few example embodiments have been described herein, those skilled in the art will readily appreciate that many modifications are possible to the example embodiments without materially departing from the novel teachings and features of the present invention. Accordingly, all such modifications are intended to be included within the scope of example embodiments as defined in the claims and their equivalents. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limiting the present invention to the specific example embodiments disclosed herein, and that modifications to the disclosed example embodiments, as well as other example embodiments, are intended to be included within the scope of the appended claims and their equivalents.

What is claimed is:

1. A flexible display device, comprising:
a flexible base substrate;
a semiconductor pattern, a gate electrode, and a gate insulation layer on the base substrate, the gate insulation layer being between the semiconductor pattern and the gate electrode;
a conductive pattern comprising a source electrode and a drain electrode, the source and drain electrodes overlapping respective sides of the semiconductor pattern;
an insulation interlayer on the gate insulation layer, between the gate electrode and the conductive pattern, and having at least one stress relief opening at a region exposed by the conductive pattern; and
a protection layer on the insulation interlayer and filling the at least one stress relief opening.

2. The flexible display device of claim 1, wherein the insulation interlayer comprises a first insulation interlayer and a second insulation interlayer, the first insulation interlayer and the second insulation interlayer being stacked on the gate insulation layer, the first and second insulation interlayers comprising inorganic materials different from each other.

3. The flexible display device of claim 2, wherein the at least one stress relief opening penetrates the second insulation interlayer.

4. The flexible display device of claim 2, wherein the at least one stress relief opening penetrates the second and first insulation Interlayers.

5. The flexible display device of claim 1, wherein a plurality of insulation interlayer patterns are in the at least one stress relief opening.

6. The flexible display device of claim 5, wherein each of the plurality of the insulation interlayer patterns extend in a same direction.

7. The flexible display device of claim 1, further comprising a capacitor on the base substrate and comprising a first capacitor electrode and a second capacitor electrode.

8. The flexible display device of claim 1, wherein the conductive pattern further comprises a data line and a driving voltage line.

9. The flexible display device of claim 8, wherein the at least one stress relief opening is between the data line and the driving voltage line.

10. The flexible display device of claim 1, further comprising;
a first electrode on the protection layer and coupled to the drain electrode;
a light emitting structure on the first electrode; and
a second electrode on the light emitting structure.

11. A method of manufacturing a flexible display device, the method comprising:
forming a semiconductor pattern, a gate electrode, and a gate insulation layer on a base substrate, the gate insulation layer being between the semiconductor pattern and the gate electrode;
forming an insulation interlayer on the gate insulation layer and covering the gate electrode and the semiconductor pattern;
forming a conductive pattern on the insulation interlayer, the conductive pattern comprising a source electrode and a drain electrode;
forming at least one stress relief opening at a region of the insulation interlayer exposed by the conductive pattern; and
forming a protection layer on the insulation interlayer and filling the at least one stress relief opening.

12. The method of claim 11, wherein the forming of the insulation interlayer comprises:
forming a first insulation interlayer on the gate insulation layer; and
forming a second insulation interlayer on the first insulation interlayer, the second insulation interlayer comprising an inorganic material different than that of the first insulation interlayer.

13. The method of claim 12, wherein the forming of the at least one stress relief opening comprises etching the second insulation interlayer utilizing the conductive pattern as an etching mask.

14. The method of claim 12, wherein the forming of the at least one stress relief opening comprises etching the second and first insulation interlayers utilizing the conductive pattern as an etching mask.

15. The method of claim 12, wherein the forming of the at least one stress relief opening comprises:
forming a photoresist pattern on the insulation interlayer, the photoresist pattern having a plurality of slits; and
patterning the insulation interlayer utilizing the photoresist pattern as an etching mask.

16. The method of claim 11, further comprising:
forming a first capacitor electrode on the base substrate; and
forming a second capacitor electrode overlapping the first capacitor electrode.

17. The method of claim 11, wherein the conductive pattern further comprises a data line and a driving voltage line.

18. The method of claim 17, wherein the at least one stress relief opening is between the data line and the driving voltage line.

19. The method of claim 11, wherein the forming of the conductive pattern on the insulation interlayer comprises:
forming contact openings penetrating the insulation interlayer to partially expose respective sides of the semiconductor pattern; and
electrically coupling the source electrode and the drain electrode to the respective sides of the semiconductor pattern through the contact openings.

20. The method of claim 11, further comprising:
forming a first electrode on the protection layer, the first electrode being coupled to the drain electrode;
forming a light emitting structure on the first electrode; and
forming a second electrode on the light emitting structure.
